(19) United States
(12) Patent Application Publication
(10) Pub. No.: US 2026/0043845 A1
(43) Pub. Date: Feb. 12, 2026

(54) CLOSED-LOOP LIQUID-COOLED BURN-IN DEVICE AND METHOD OF CONTROLLING THE SAME

(71) Applicant: Expert International Mercantile Corporation, Hsinchu (TW)

(72) Inventors: WEI-CHIH SUN, Hsinchu (TW); Chia-Chun Ho, Hsinchu (TW); Wen-Hsu Chang, Hsinchu (TW)

(21) Appl. No.: 18/969,441

(22) Filed: Dec. 5, 2024

(30) Foreign Application Priority Data
Aug. 9, 2024 (TW) 113130055

(51) Int. Cl. G01R 31/28; H05K 7/20

(52) U.S. Cl. CPC G01R 31/2877; G01R 31/2862; G01R 31/2875; H05K 7/20272; H05K 7/20281

(57) ABSTRACT

A closed-loop liquid-cooled burn-in device includes a water tank and at least one test socket. The water tank is in fluid connection with the at least one test socket by a loop. The water tank has a first reservoir and a second reservoir. The first reservoir stores a low-temperature cooling liquid, and the second reservoir stores a high-temperature cooling liquid. The first reservoir provides a heating unit for heating up the low-temperature cooling liquid to control the temperature of the cooling liquid supplied to the at least one test socket.

### RELATED APPLICATIONS

This application claims priority to Taiwan Application Serial Number 113130055, filed on Aug. 9, 2024, which is incorporated by reference herein in its entirety.

### BACKGROUND OF THE INVENTION

### Field of the Invention

The present disclosure relates to burn-in test devices, and more particularly to a burn-in test device comprising a liquid cooling mechanism for regulating a test temperature and a method of controlling the liquid-cooled burn-in device.

### Description of the Prior Art

Packaged integrated circuits (IC) usually undergo a burn-in test for a specific time period to ensure that IC products remain operable in harsh environments. A packaged chip (a device under test, DUT) is received in a test socket, and the bottom of the chip is electrically connected to multiple signal contacts in the test socket. A lid of the test socket functions as a portion of a liquid cooling loop. The lid is adapted to come into contact with the chip to regulate the temperature of the chip under test. The lid comprises multiple cooling fins arranged in a specific pattern, allowing the lid to undergo cooling by convection. The lid further comes with a fan disposed above the cooling fins to enhance the convection. The liquid cooling loop essentially comprises a cold water network and a hot water network. The cold water network transports a cooling liquid of a low temperature to the test socket. The hot water network recycles the cooling liquid from the test socket. The liquid cooling loop effectively suppresses test temperature to keep the temperature of the chip under test at a specific temperature steadily. However, if the temperature of the cooling liquid of the cold water network is overly low, the cooling speed will be overly high, precluding the steady control of temperature variations.

The liquid cooling loop is formed through connecting flexible tubes and pipes, but it is possible for the cooling liquid to leak via connection interfaces. When inappropriately operated, the flexible tubes are likely to rupture or sever, leading to leakage of the cooling liquid. Once the cooling liquid leaks, the test socket will lose its temperature control function.

### SUMMARY OF THE INVENTION

The disclosure provides a water tank that has a heating function to enhance temperature control efficiency, preclude an overly large difference between cold water temperature and hot water temperature, for example, a temperature difference greater than 20° C., upon a system start, preclude overly long standby time, and preclude excessive temperature fluctuations.

Furthermore, the disclosure entails detecting and monitoring the water level in the water tank to ensure that the start or recovery of a recycling mechanism results in the complete withdrawal or filling of a liquid in a closed loop, precluding a loss of the cooling liquid.

In view of the aforesaid drawbacks of the prior art, it is an objective of the disclosure to provide a closed-loop liquid-cooled burn-in device, comprising: a loop having a cold water network and a hot water network; and a water tank and at least one test socket, with the water tank in fluid connection with the at least one test socket by the loop. The water tank has a first reservoir and a second reservoir. The first reservoir stores a low-temperature cooling liquid, and the second reservoir stores a high-temperature cooling liquid. The first reservoir provides a heating unit for heating up the low-temperature cooling liquid to control the temperature of the cooling liquid supplied to the at least one test socket.

In an embodiment, the first reservoir is in fluid connection with the at least one test socket by the cold water network, and the second reservoir is in fluid connection with the at least one test socket by the hot water network.

In an embodiment, the first reservoir is in fluid connection with a heat exchange unit by the cold water network, and the second reservoir is in fluid connection with the heat exchange unit by the hot water network.

In an embodiment, the heating unit is attached to the outer wall surface of the first reservoir and electrically connected to a circuit board.

In an embodiment, the heating unit is a PTC device.

Another objective of the disclosure is to provide a method of controlling a closed-loop liquid-cooled burn-in device. The method comprises the steps of: providing a loop for supplying a cooling liquid from a water tank to at least one test socket; keeping a pressure value of the water tank within a predetermined range of less than 1 atm; recycling the cooling liquid from the loop to the water tank with one or more pumps when the loop becomes an open circuit; and reading by a water-level sensing unit a water level of the water tank, and determining that the cooling liquid does not incur any substantial loss otherwise caused by the open circuit when the water level of the water tank reaches a predetermined water level.

In an embodiment, the method further comprises the step of determining by the water-level sensing unit that the burn-in device operates in a normal state when the water level of the water tank reaches a first predetermined position, the normal state being indicative of circulation of the cooling liquid in the loop.

In an embodiment, the method further comprises the step of determining by the water level sensing unit that the burn-in device operates in a maintain state when the water level of the water tank reaches a second predetermined position, the maintain state being indicative of the cooling liquid having been recycled to the water tank and not existing in the loop.

In an embodiment, the second predetermined position is higher than the first predetermined position.

In an embodiment, a pressure value of the water tank is kept within a predetermined range of less than 1 atm, and the predetermined range is 80˜85 kPa or 0.6˜0.8 atm.

The aforesaid aspects and other aspects of the disclosure are illustrated by non-restrictive, specific embodiments, depicted by accompanying drawings, described below and thus rendered clearer.

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1 shows a closed-loop liquid-cooled burn-in device according to an embodiment of the disclosure.

FIG. 2A and FIG. 2B are a see-through view and a front view of a water tank of the liquid-cooled burn-in device respectively.

FIG. 3A and FIG. 3B show a cooling means for test sockets.

FIG. 4 shows the water tank according to an embodiment of the disclosure.

FIG. 5A and FIG. 5B schematically show that the liquid-cooled burn-in device becomes a closed circuit and an open circuit respectively.

FIG. 6 is a flowchart of the control of the closed-loop liquid-cooled burn-in device according to the disclosure.

FIG. 7 is a flowchart of the control of the closed-loop liquid-cooled burn-in device according to the disclosure.

FIG. 8 depicts the relationship between a control state and a water level.

### DETAILED DESCRIPTION OF THE EMBODIMENTS

The disclosure is fully described below, depicted by drawings, and illustrated by specific embodiments. However, the subject matter claimed by the disclosure can be specifically implemented in various ways; hence, the subject matter falling within the scope of or claimed by the disclosure is not restricted to any specific embodiments of the disclosure. The specific embodiments of the disclosure serve illustrative purposes only. Likewise, the disclosure is aimed at defining reasonably broad scope of the subject matter falling within the scope of or claimed by the disclosure.

The expression “in an embodiment” used herein does not necessarily refer to the same specific embodiment. Furthermore, the expression “in other (a few/some) embodiments” used herein does not necessarily refer to different specific embodiments. The expressions are aimed at, for example, enabling the claimed subject matter to include the combination of all or part of exemplary, specific embodiments.

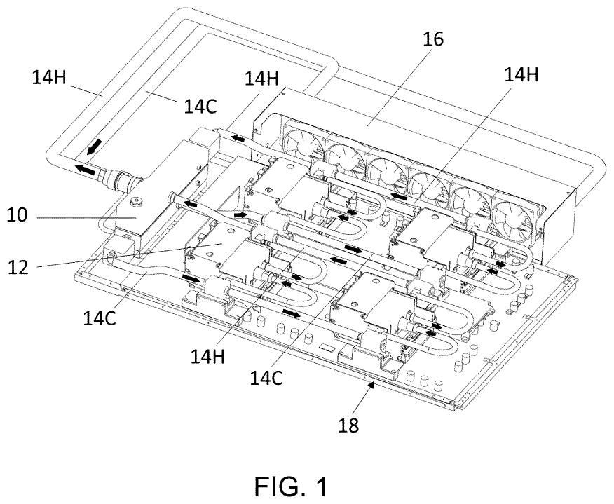

FIG. 1 shows a closed-loop liquid-cooled burn-in device according to an embodiment of the disclosure. The closed-loop liquid-cooled burn-in device of the disclosure essentially comprises a water tank (10), multiple test sockets (12), a liquid cooling loop (14C, 14H) and a heat exchange unit (16).

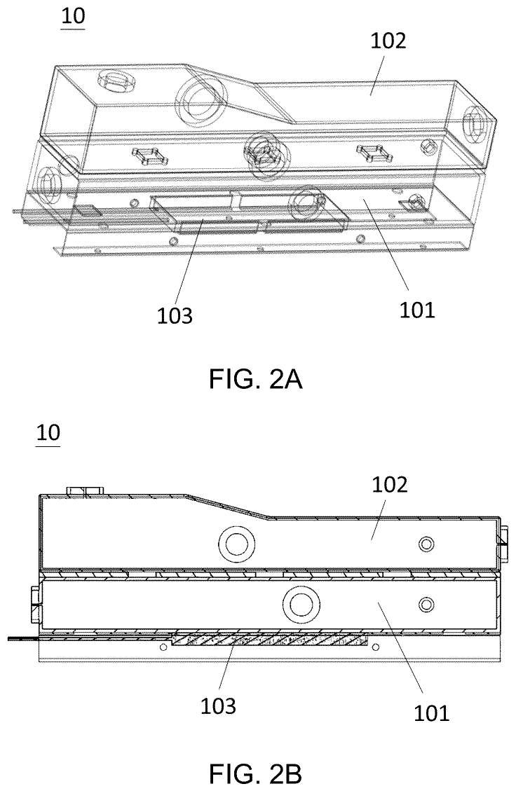

The water tank (10) is essentially for use in distributing low-temperature and high-temperature cooling liquids. FIG. 2A and FIG. 2B are a see-through view and a front view of the water tank (10) respectively. The water tank (10) has a first (bottom) reservoir (101) connected to a cold water network (14C) and a second (top) reservoir (102) connected to a hot water network (14H). Referring to FIG. 1 and FIG. 2A, the first reservoir (101) has an inlet connected to the heat exchange unit (16) and two outlets connected to the test sockets (12), whereas the second reservoir (102) has an outlet connected to the heat exchange unit (16) and two inlets connected to the test sockets (12). The first reservoir (101) and the second reservoir (102) are insulated from each other. Preferably, the first reservoir (101) and the second reservoir (102) are separated by an appropriate distance or insulated from each other by a heat insulating material. The bottom of the first reservoir (101) is provided with a heating unit (103), such as a PTC device, and receives control signals from a circuit board (18). The heating unit (103) is configured to heat up a cooling liquid in the first reservoir (101) to controllably keep a cooling liquid temperature in the cold water network (14C) above a specific temperature to prevent the heat exchange unit (16) from causing excessive cooling. If the cooling liquid temperature transmitted from the heat exchange unit (16) to the first reservoir (101) is lower than a predetermined temperature, or the cooling liquid temperature in the first reservoir (101) is lower than a predetermined temperature, or a cooling liquid temperature upstream from the test sockets (12) is lower than a predetermined temperature, the heating unit (103) will be started. In this embodiment, the heating unit (103) is attached to the outer wall surface of the first reservoir (101), but the disclosure is not limited thereto.

The liquid cooling loop (14C, 14H) is a network comprising manifolds and a channel and space and further comprising a cold water network (14C) and a hot water network (14H), but the disclosure is not limited thereto. The cold water network (14C) recycles a low-temperature cooling liquid from the heat exchange unit (16) to the water tank (10) and then from the water tank (10) to the test sockets (12). The hot water network (14H) recycles a high-temperature cooling liquid from the test sockets (12) to the water tank (10), and from the water tank (10) to the heat exchange unit (16).

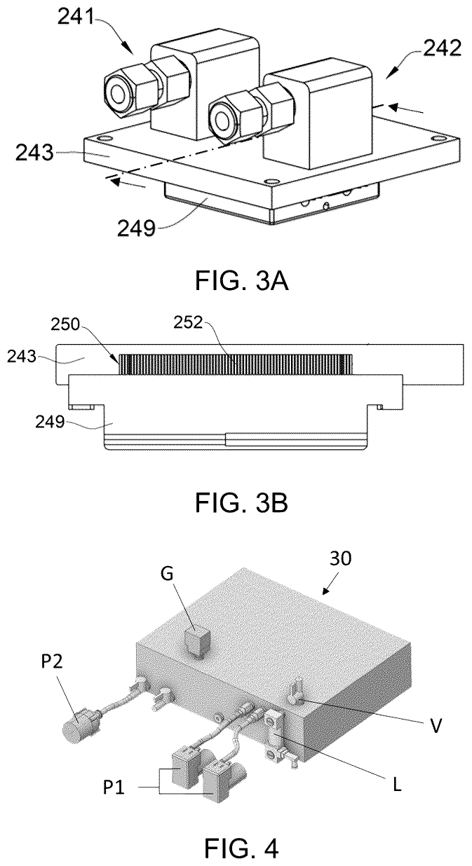

The test sockets (12) are fixed to and electrically connected to a circuit board (18). The test sockets (12) receive test signals from the circuit board (18), providing a test environment to a device under test (DUT) (not shown). The DUT is placed in the test sockets (12) to undergo a test. The test sockets (12) essentially comprises a base for containing the DUT and a cooling means. FIG. 3A and FIG. 3B show a cooling means for the test sockets, comprising an admitting port (241) connected to the cold water network (14C) and a discharging port (242) connected to the hot water network (14H). The admitting port (241) and the discharging port (242) are jointly connected to a water cooling plate (243), and the bottom of the water cooling plate (243) provides a contact element (249) for coming into contact with the surface of the DUT. The water cooling plate (243) and the contact element (249) are essentially made by a metal processing process. FIG. 3B is a cross-sectional view taken along the dashed line of FIG. 3A, showing a heat exchange channel (250) jointly defined through connecting the water cooling plate (243) and the contact element (249). The cooling liquid enters the heat exchange channel (250) via the admitting port (241) and then exits the heat exchange channel (250) via the discharging port (242). The heat exchange channel (250) has therein multiple fins (252) whereby the cooling liquid in the heat exchange channel (250) comes into contact with the fins (252), enhancing heat exchange. In a variant embodiment of the test sockets (12) of the disclosure, for example, the admitting port (241) or the discharging port (242) is provided with a pump for controlling the volumetric flow rate of the cooling liquid.

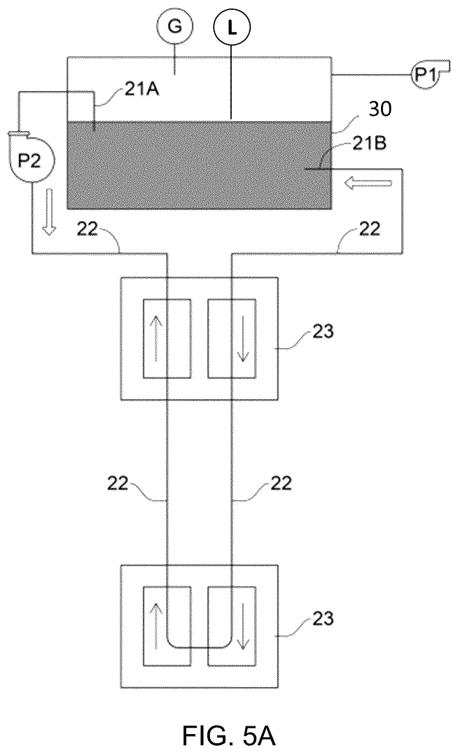

FIG. 4 shows a framework of a water tank (30) according to an embodiment of the disclosure. The framework is applicable to the water tank (10) of FIG. 1, for example, the first reservoir (101) or the second reservoir (102). The water tank (30) comprises a first pump (P1), a second pump (P2), a pressure sensing unit (G) and a water-level sensing unit (L).

The first pump (P1) is a gas pump for extracting air from the water tank (30) such that the water tank (30) is in a negative pressure state to keep the water tank (30) in a predetermined air pressure range, for example, 0.6˜0.8 atm, or 80˜85 kPa, to prevent air from being excessively admitted into the liquid cooling loop.

The second pump (P2) is a liquid pump connected to the cold water network (14C) of FIG. 1 to control the direction of circulation of the cooling liquid in the closed loop, for example, delivering the cooling liquid from the first reservoir (101) of FIG. 1 to the test sockets (12) or recycling the cooling liquid from the test sockets (12) to the first reservoir (101).

The pressure sensing unit (G) is configured to read a pressure change in the water tank (30). For example, the pressure sensing unit (G) causes a monitoring end to generate an alarm signal when the air pressure in the water tank (30) increases rapidly and exceeds the predetermined range. In a specific embodiment, the pressure sensing unit (G) performs high-frequency monitoring, for example, generating 20 or more readings per second.

The water-level sensing unit (L) is configured to read and determine whether the cooling liquid in the water tank (30) reaches a predetermined water level. For example, the water-level sensing unit (L) starts to read a water level in response to the alarm signal generated when the pressure sensing unit (G) senses a pressure change, confirming whether the cooling liquid recycled to the water tank (30) has decreased and thus has to be supplied again. The water-level sensing unit (L) is a mechanical unit, electronic unit or hybrid unit, but the disclosure is not limited thereto.

The water tank (30) further provides a valve (V) configured to connect to a cooling liquid source, allowing the cooling liquid to be supplied and delivered to the water tank (30) via the valve (V).

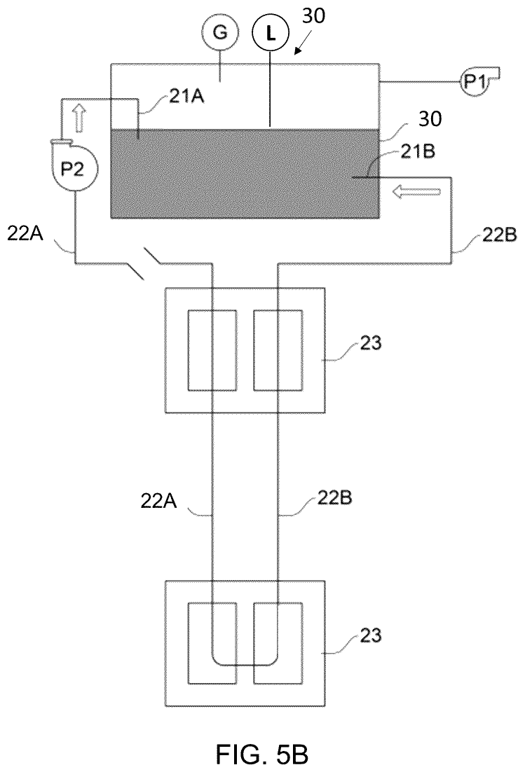

FIG. 5A and FIG. 5B schematically show that the liquid-cooled burn-in device becomes a closed circuit and an open circuit respectively. For the sake of illustration and comprehension, the schematic diagrams omit the heat exchange unit (16) of FIG. 1. FIG. 5A schematically shows a framework of the closed-loop liquid-cooled burn-in device of the disclosure, which comprises the water tank (30), a transport pipeline (22) and a plurality of test sockets (23). The water tank (30), the transport pipeline (22) and the test sockets (23) together form a closed loop in which the cooling liquid circulates.

The water tank (30) has a receiving space for holding a cooling liquid, such as water or any chemical liquid well known among persons skilled in the art. The water tank (30) essentially comprises a mechanically strong casing, especially a casing capable of withstanding an enormous pressure difference (say 40 kPa) without being deformed. In an embodiment, the water tank is made of acrylic plates (PMMA), has dimensions of 150 mm*200 mm*150 mm, and has walls which are 10 mm in thickness. The water tank (30) has a first port (21A) and a second port (21B). The cooling liquid enters and exits the water tank (30) via the first port (21A) and the second port (21B) respectively.

The transport pipeline (22) has two ends connected to the first port (21A) and the second port (21B) of the water tank (30) respectively. In practice, the transport pipeline (22) is a circulation path defined by a combination of one or more pipes, flexible tubes, valves and/or connectors. The transport pipeline (22) can be appropriately laid out and extended above the circuit board and passed through target sockets according to the framework of the burn-in device. The transport pipeline (22) further comprises a valve (not shown) for controlling the flow rate or distribution of the cooling liquid.

The test sockets (23) are electrically connected to the circuit board (18) of FIG. 1 and operated to perform various tests on the DUTs received in the test sockets (23). The test sockets (23) are appropriately configured to be in fluid connection with the transport pipeline (22). Specifically speaking, the test sockets (23) provide specific connection interfaces whereby the cooling liquid of the transport pipeline (22) passes through a portion of the test sockets (23) as shown in FIG. 3A, and then the cooling liquid returns to the transport pipeline (22) from the connection interfaces of the test sockets (23) after absorbing heat. It is noteworthy that the framework disclosed herein is merely schematically shown and is not restrictive of the disclosure; thus, the framework disclosed herein can be replaced with any possible frameworks.

FIG. 5B schematically shows the flow direction of the cooling liquid after the loop has become an open circuit. When the transport pipeline (22) is severed, the pressure sensing unit (G) reads a pressure change in the water tank (30) or the whole loop, for example, the air pressure in the water tank (30) increases rapidly and exceeds a predetermined range required to maintain a negative pressure.

The transport pipeline (22) connected to the second port (21B) confines the cooling liquid to the loop as soon as the transport pipeline (22) severs, because the water tank (30) or the whole loop remains in a negative pressure state. By contrast, the cooling liquid in the transport pipeline (22A) connected to the first port (21A) is recycled to the water tank (30), because the second pump (P2) immediately shuts down and changes the flow direction before it starts. After the transport pipeline (22) has severed, the pressure in the loop increases rapidly to cause the pressure in the receiving space of the water tank (21) to approach the atmospheric pressure in external space. To preclude the leakage of the cooling liquid through the point of severance because of pressure equilibrium, the first pump (P1) starts in response to a severance-induced pressure change. The first pump (P1) extracts air out of the water tank (30) continuously, and thus the cooling liquid in the transport pipeline (22B) is recycled to the water tank (21), and external air enters the transport pipeline (22B) via the point of severance. A control end instructs the test process to stop until the normal operation of the loop resumes.

After the loop has become an open circuit, the water-level sensing unit (L) is started to read the water level of the cooling liquid. The first pump (P1) operates continuously to maintain a negative pressure state in the water tank (30). The second pump (P2) continuously recycles the cooling liquid from the transport pipeline (22A) to the water tank (30), allowing the water level of the cooling liquid to rise. When the water level reaches a predetermined position, it is certain that a considerable amount of the cooling liquid has been recycled, leaving no trace of residual cooling liquid in the transport pipeline (22A). Then, workers inspect the transport pipeline (22) until the open circuit is troubleshot.

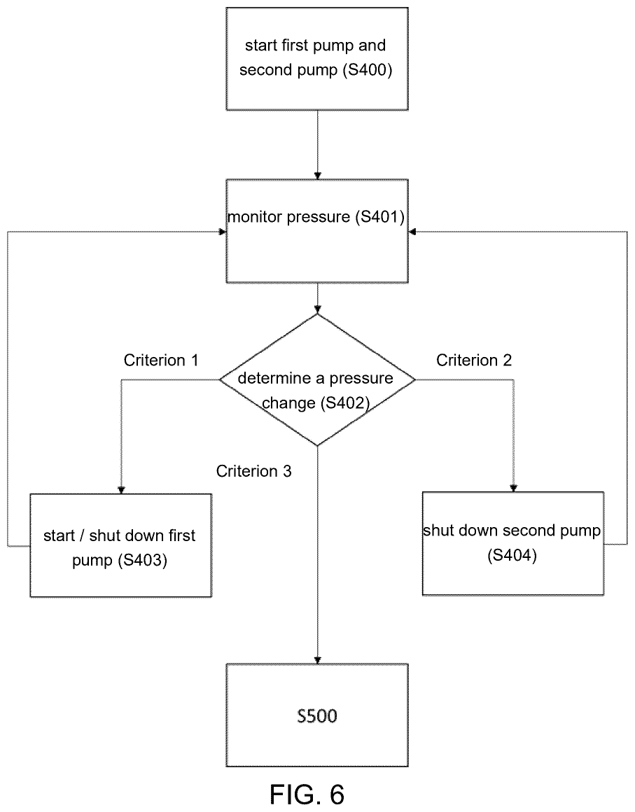

FIG. 6 is a flowchart of the control of the closed-loop liquid-cooled burn-in device according to the disclosure, showing that the process of control comprises steps S400 through S404.

Step S400: Start the first pump (P1) and the second pump (P2). The first pump (P1) extracts air out of the water tank (30) continuously to maintain a negative pressure state in the water tank (30). The second pump (P2) continuously delivers the cooling liquid from the water tank (30) to the transport pipeline (22), and thus the cooling liquid circulates in the closed loop continuously, as shown in FIG. 5A.

Step S401: The pressure sensing unit (G) monitors the pressure in the water tank (30) continuously to obtain a real-time pressure value. The pressure sensing unit (G) generates a plurality of readings (real-time pressure values) per second and sends the readings to the control end to allow the control end to calculate the pressure difference between a preceding pressure value and a current pressure value, an average pressure value, and a pressure change within a time period (for example, rate of change of atm/S).

Step S402: Control unit compares the real-time pressure value, pressure change, average pressure and pressure difference according to a predetermined range (for example, greater than a valve, less than a valve, or between two valves). In an embodiment, the predetermined range is a range of less than 1 atm. Preferably, the predetermined range is 0.6˜0.8 atm, but the disclosure is not limited thereto.

When a real-time pressure value or consecutive multiple pressure values exceed the predetermined range (satisfying criterion 1), i.e., a real-time pressure value or consecutive multiple pressure values are greater than the upper limit of the predetermined range or less than the lower limit of the predetermined range, the process flow of the method of the disclosure exits step S402 to enter step S403. When the pressure difference between two consecutive pressure values measured at two consecutive points in time respectively is greater than a critical pressure difference and greater than the average pressure during a specific time period (satisfying criterion 2), the process flow of the method of the disclosure exits step S402 to enter S404. When a pressure change exceeds a critical rate of change and/or the real-time pressure value is greater than the upper limit of a predetermined range (satisfying criterion 3), indicative of a rapid increase of the pressure in the water tank (30) and a chance of resultant rupture or severance of the transport pipeline (22), the process flow of the method of the disclosure exits step S402 to enter step S500.

Step S403: The first pump (P1) switches between start and shutdown according to a predetermined start and shutdown strategy, the process flow of the method of the disclosure returns to step S401 and S402.

Step S404: Shut down the second pump (P2) and then wait for a predetermined time period before starting the second pump (P2) again, causing the process flow of the method of the disclosure to return to step S401 and S402. In an embodiment, the second pump (P2) is shut down for two seconds to stop circulation and then started again to continue with the circulation in the same direction.

The burn-in device can still perform conventional tests throughout the process flow loop starting from step S400 and ending at step S404, because the cooling liquid still circulates in the closed loop without leaking.

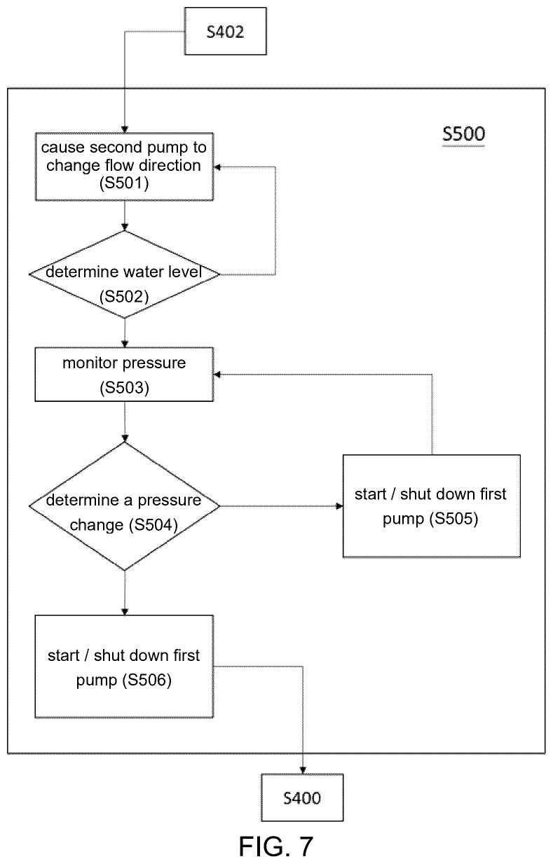

FIG. 7 is a flowchart of the control of the closed-loop liquid-cooled burn-in device according to the disclosure, showing the control process flow, i.e., step S500, comprising steps S501˜S506.

When step S402 determines that pressure anomaly occurs (satisfying the criterion that a pressure change exceeds a critical rate of change and/or the real-time pressure value is greater than the upper limit of a predetermined range), the process flow of the method of the disclosure enters step S500.

Step S501: Cause the second pump (P2) to change the flow direction to stop supplying the cooling liquid to the test sockets (23) and recycle the cooling liquid to the water tank (30).

Step S502: The water level sensing unit (L) reads the water level in the water tank (30). If the water level reaches a predetermined position, it will mean that a volumetric amount of the cooling liquid has been recycled to the water tank (30), without any loss of excessive cooling liquid because of an open circuit event; thus, the process flow of the method of the disclosure enters step S503, otherwise the process flow of the method of the disclosure continues with step S501.

Step S503: The pressure sensing unit (G) monitors the pressure in the water tank (30) continuously to calculate the pressure difference between a preceding pressure value and a current pressure value, an average pressure value, and a pressure change within a time period. Likewise, the pressure sensing unit (G) generates the same amount of readings per second or even more readings per second to enhance monitoring sensitivity.

Step S504: The control end compares the real-time pressure value, pressure change, average pressure and pressure difference according to a predetermined range. In an embodiment, the predetermined range is a range of less than 1 atm. Preferably, the predetermined range is 0.6˜0.8 atm. Alternatively, step S504 is based on a predetermined range different from that step S402 is based on.

When a real-time pressure value or consecutive multiple real-time pressure values exceed the predetermined range, i.e., a real-time pressure value or consecutive multiple pressure values are greater than the upper limit of a predetermined range or less than the lower limit of the predetermined range, the process flow of the method of the disclosure exits step S504 to enter step S505. When a real-time pressure value or consecutive multiple real-time pressure values fall within the predetermined range and/or the pressure change exhibits a normal decrease, the process flow of the method of the disclosure exits step S504 to enter S506. The steady decrease indicates that the monitored pressure change satisfies a rate of change.

Step S505: The first pump (P1) switches between start and shutdown according to a predetermined start and shutdown strategy, and the process flow of the method of the disclosure returns to step S503 and S504 to carry out the determination process again. In an embodiment, the first pump (P1) and the second pump (P2) can start simultaneously to simultaneously maintain a negative pressure state in the water tank (30) and recycle the cooling liquid to the water tank (30). It is noteworthy that the start and shutdown of the first pump (P1) and the second pump (P2) are synchronous or asynchronous or are carried out according to a predetermined rule to maintain a target negative pressure state in the loop and thereby cause the cooling liquid to flow back to the water tank (30).

Step S506: The first pump (P1) switches between start and shutdown according to a predetermined start and shutdown strategy, and the process flow of the method of the disclosure returns to step S400 in order for normal closed-loop circulation to occur.

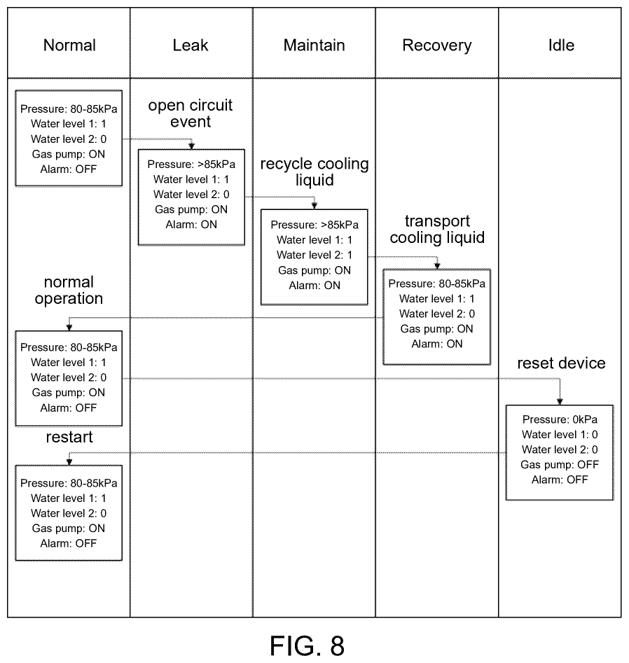

FIG. 8 depicts the relationship between a control state and a water level, but the disclosure is not limited thereto.

In normal state, the pressure in the water tank, as read by the pressure sensing unit, ranges from 80 kPa to 85 kPa (a predetermined pressure range). Water level 1 denotes a first predetermined position of the water level of the cooling liquid in the water tank during circulation in the closed loop. Water level 2 denotes a second predetermined position expected of the cooling liquid fully recycled to the water tank instead of circulating in the loop; thus, the second predetermined position is higher than the first predetermined position. The reading “1” of water level 1 indicates that the first predetermined position is satisfied. The reading “0” of water level 2 indicates that the second predetermined position is not satisfied. At this point in time, the gas pump operates continuously, and there is no alarm signal.

In leak state, a specific point of the loop develops an open circuit, and thus the pressure in the water tank increases to exceed 85 kPa. At this point in time, the control end generates an alarm signal in response to a change in pressure readings. One or more liquid pumps (for example, the second pump P2 of FIG. 5B) bring about reverse flow to recycle the cooling liquid from the loop to the water tank.

In maintain state, although the water tank pressure is still greater than 85 kPa, almost all the cooling liquid in the loop is recycled to the water tank. The reading “2” of water level 2 indicates that the water level satisfies the second predetermined position and that the cooling liquid does not incur any substantial loss otherwise caused by an open circuit event. If the reading of water level 2 is still not “2”, workers may carry out an inspection and add an appropriate amount of cooling liquid.

In recovery state, the flow direction of one or more liquid pumps is switched to transport the cooling liquid from the water tank to the loop anew. Since the water level in the water tank drops, the reading of water level 2 is “0”. Then, the control state returns to the normal state.

However, if the operation in the normal state is still confronted with any other issues or has to be corrected anew, the control state may proceed to the reset state to zero the readings of pressure as well as the readings of water level 1 and water level 2 and cause the gas pump to shut down. Afterward, the liquid-cooled burn-in device is restarted.

Therefore, a closed-loop liquid-cooled burn-in device and a method of controlling the same of the disclosure are described above and illustrated by drawings. The embodiments (or technical solutions/features) of the disclosure are not necessarily for sole use or application. Persons skilled in the art may integrate or partially integrate at least any two of the embodiments (or technical solutions/features) into the same embodiment as needed. Specific embodiments of the disclosure merely serve illustrative purposes. All changes can be made to the disclosure without departing from the spirit and scope of the claims of the disclosure and still fall within the scope of the claims of the disclosure. Therefore, specific embodiments described herein are not restrictive of the disclosure, whereas the true scope and spirit of the disclosure shall be defined by the appended claims.

What is claimed is:

1. A closed-loop liquid-cooled burn-in device, comprising:
a loop having a cold water network and a hot water network; and
a water tank and at least one test socket, the water tank being in fluid connection with the at least one test socket by the loop,
wherein the water tank has a first reservoir and a second reservoir, the first reservoir storing a low-temperature cooling liquid, and the second reservoir storing a high-temperature cooling liquid,
wherein the first reservoir further provides a heating unit for heating up the low-temperature cooling liquid to control a temperature of the cooling liquid supplied to the at least one test socket.

2. The closed-loop liquid-cooled burn-in device of claim 1, wherein the first reservoir is in fluid connection with the at least one test socket by the cold water network, and the second reservoir is in fluid connection with the at least one test socket by the hot water network.

3. The closed-loop liquid-cooled burn-in device of claim 1, wherein the first reservoir is in fluid connection with a heat exchange unit by the cold water network, and the second reservoir is in fluid connection with the heat exchange unit by the hot water network.

4. The closed-loop liquid-cooled burn-in device of claim 1, wherein the heating unit is attached to an outer wall surface of the first reservoir and electrically connected to a circuit board.

5. The closed-loop liquid-cooled burn-in device of claim 4, wherein the heating unit is a PTC device.

6. A method of controlling a closed-loop liquid-cooled burn-in device, comprising the steps of:
providing a loop for supplying a cooling liquid from a water tank to at least one test socket;
keeping a pressure value of the water tank within a predetermined range of less than 1 atm;
recycling the cooling liquid from the loop to the water tank with one or more pumps when the loop becomes an open circuit; and
reading by a water-level sensing unit a water level of the water tank, and determining that the cooling liquid does not incur any substantial loss otherwise caused by the open circuit when the water level of the water tank reaches a predetermined position.

7. The method of claim 6, further comprising the step of determining by the water-level sensing unit that the burn-in device operates in a normal state when the water level of the water tank reaches a first predetermined position, the normal state being indicative of circulation of the cooling liquid in the loop.

8. The method of claim 7, further comprising the step of determining by the water-level sensing unit that the burn-in device operates in a maintain state when the water level of the water tank reaches a second predetermined position, the maintain state being indicative of the cooling liquid having been recycled to the water tank and not existing in the loop.

9. The method of claim 8, wherein the second predetermined position is higher than the first predetermined position.

10. The method of claim 6, wherein a pressure value of the water tank is kept within a predetermined range of less than 1 atm, and the predetermined range is 80˜85 kPa or 0.6˜0.8 atm.
